(19) United States
(12) Patent Application Publication
(10) Pub. No.: US 2005/0248417 A1
(43) Pub. Date: Nov. 10, 2005

(54) Controllable transient insertion device

(76) Inventors: Mihail Eduard Popescu, St-Leonard (CA); John Downey, Ottawa (CA); Peter W. Phelps, Nepean (CA); Andre Brissette, Aylmer (CA)

Correspondence Address: BORDEN LADNER GERVAIS LLP, WORLD EXCHANGE PLAZA, 100 QUEEN STREET SUITE 1100, OTTAWA, ON, K1P 1J9, CA

(21) Appl. No.: 10/840,351

(22) Filed: May 7, 2004

(51) Int. Cl. H03L 7/00

(52) U.S. Cl. 331/158

(57) ABSTRACT

An apparatus is provided for modifying a timing signal generated by a timing signal generator. The timing signal is modified indirectly by first modifying a power supply signal from a power supply upon which the timing signal generator is dependent to generate the timing signal. Initiating an introduction of at least one transient signal component of variable length by a transient insertion device into the power supply signal causes the timing signal generator to be disrupted and at least one transient signal component to be introduced within the timing signal. A particular implementation of the invention is an electrical circuit consisting of both active and passive electronic components.

### FIELD OF THE INVENTION

The invention relates to clocking or timing signals and in particular to faults or glitches in such signals.

### BACKGROUND OF THE INVENTION

Many electronic devices today require some form of temporal synchronization to ensure proper operation. Therefore timing signals are common in cell phones, computers, telecommunications switches, and a multitude of other devices. Timing signals commonly operate at frequencies ranging from tens of hertz to Gigahertz.

Systems with timing signals have the disadvantage that a fault relating to a timing signal can have a detrimental overall effect in a system. In a complex system it can be very difficult to determine where a fault initially occurred. Faults occurring in the system are often intermittent, which can make them difficult to observe. For example, if a customer reports to a vendor a non-fatal system failure in a piece of equipment and sends the piece of equipment back to the vendor to identify a source of the failure, the vendor may not be able to observe the failure. In attempting to identify the actual cause of the fault it is necessary to monitor the system until the same fault occurs again, which may be infrequently, if ever. Even if the system is constantly monitored and a fault is observed there is no guarantee that a reason for the fault will be able to be pinpointed and a root cause discovered. If the effects of the fault are known and the effects of the failure can be simulated in a controlled manner by acting on a particular component of the piece of equipment, then a clue to the source of the problem may be deduced. At this point steps. can be taken to overcome the problem that is the source of the failure.

In some cases a fault may be a function of a timing signal generator or at some other peripheral element in the system. In a situation where it is believed that the timing signal generator is a primary source of the fault, it is desirable to be able to simulate a controlled fault of the timing signal generator and compare system results of the controlled fault to results of an “in-the-field” failure.

A device for enabling the effective simulation of a system level failure based on a known cause would be extremely beneficial for improving the fault tolerance of future iterations of a device or system and allow understanding of the workings of individual components of the system and system failure modes.

### SUMMARY OF THE INVENTION

An apparatus is provided for modifying a timing signal generated by a timing signal generator. The timing signal is modified indirectly by first modifying a power supply signal from a power supply upon which the timing signal generator is dependent to generate the timing signal. Initiating an introduction of at least one transient signal component of variable length into the power supply signal by using a transient insertion device causes the timing signal generator to be disrupted and at least one transient signal component to be introduced into the timing signal.

Activation of a trigger mechanism supplies an input to a transient component generator. The transient component generator generates a modified power supply signal that is used to power the timing signal generator. The timing signal output of the timing signal generator is therefore also modified in sympathy with the transient component generator.

A transient component duration adjuster supplies an input to the transient component generator. The transient component duration adjuster input controls a duration of at least one transient signal component which is generated by the transient component generator.

The transient component generator uses inputs supplied from the transient component trigger and the transient component duration adjuster to create the modified power supply signal which is used in modifying the timing signal output by the timing signal generator.

An output from the transient component generator is used by a transient detector to provide visible notification that the transient component generator has generated the modified power supply signal which is used in modifying the timing signal output by the timing signal generator.

An implementation of a particular embodiment provided by the invention is an electrical circuit consisting of both active and passive electronic components.

The invention allows the exploration of fault modes in system timing signals and leads to a better understanding of individual system components, for example timing signal generators, which results in design of better hardware and software to account for such fault modes.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

Preferred embodiments of the invention will now be described with reference to the attached drawings in which:

FIG. 1 is a schematic of a block diagram of a controllable transient insertion device according to the invention;

FIG. 2 is a circuit diagram of the controllable transient insertion device of FIG. 1;

FIG. 3 is a schematic of a block diagram in which a controllable transient insertion device according to the invention is used in combination with a phase locked loop (PLL) clocking signal generating apparatus; and

FIG. 4 is a timing diagram of signals measured at various test points of the controllable transient insertion device circuit shown in FIG. 2.

### DETAILED DESCRIPTION OF THE PREFERRED EMBODIMENTS

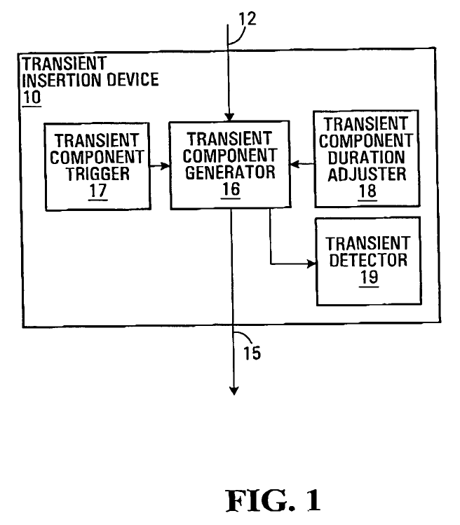

Referring to FIG. 1, a transient insertion device 10 comprises a transient component generator 16, a transient component trigger 17, a transient component duration adjuster 18, and a transient detector 19. The transient insertion device 10 also has an input 12 and an output 15. The input 12 supplies a first input to the transient component generator 16. The transient component trigger 17 supplies a second input to the transient component generator 16. The transient component duration adjuster 18 supplies a third input to the transient component generator 16. The transient component generator 16 is connected via a first output to the output 15 of the transient insertion device 10. The transient detector 19 receives a second output from the transient component generator 16. The transient detector 19 has an output to provide visible notification of a successfully performed action.

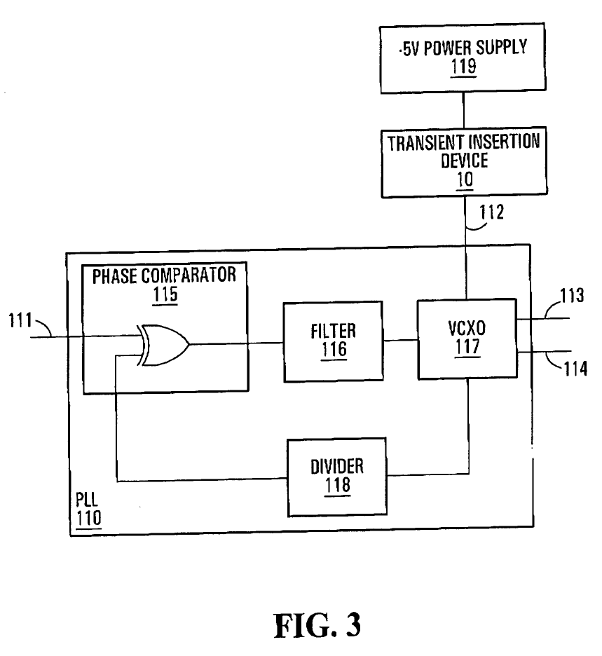

In operation, the input 12 of the transient insertion device 10 is a power supply signal that is used to power a timing signal generator (not shown in FIG. 1, but described hereinafter in relation to FIG. 3). The input 12 is supplied to the first input of the transient component generator 16. The transient component trigger 17 supplies the second input to the transient component generator 16 in the form of a triggering input that is used to initiate modification of the power supply signal. The transient component duration adjuster 18 supplies the third input to the transient component generator 16 in the form of an input used to control duration of at least one transient signal component of a signal output by the transient component generator 16. The transient component generator 16 uses the inputs supplied from the transient component trigger 17 and the transient component duration adjuster 18 to act upon the power supply signal supplied to the first input of the transient component generator 16 to generate a modified power supply signal having at least one transient signal component of variable duration at the first output of the transient component generator 16. The modification of the timing signal generated by the timing signal generator occurs as a function of the modified power supply signal.

The transient detector 19 receives the second output from the transient component generator 16. The transient detector 19 uses the second output from the transient component generator 16 to determine whether the transient component generator 16 has generated the modified power supply signal. The transient detector 19 also generates a visible notification of when the transient detector 19 determines the transient component generator 16 has in fact generated the modified power supply signal used to modify the timing signal.

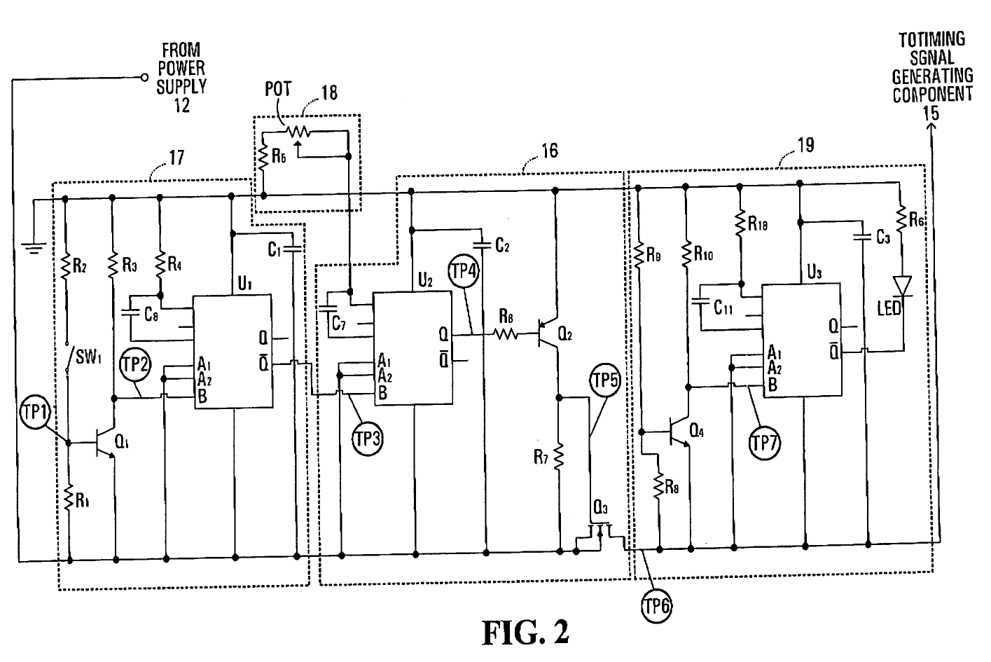

Referring to FIG. 2, discrete electronic components that form the transient component generator 16, the transient component trigger 17, the transient component duration adjuster 18 and the transient detector 19 are grouped together respectively within the overall circuit diagram.

In the embodiment of FIG. 2 active components in the transient component generator 16 and the transient component trigger 17 are electrically powered by a power supply (not shown) which is coupled to the transient component generator 16 via the first input 12. More generally, the transient component trigger 17 can be powered by the power supply that is coupled to the transient insertion device 10 or a power supply dedicated to the transient component trigger 17.

The transient component trigger 17 is comprised of transistor Q1 biased in a conventional manner. An emitter of transistor Q1 and a first terminal of resistor R1 are connected to a first node that is connected to the input 12 of the transient insertion device 10. A manually activated switch SW1 is located between a second terminal of resistor R1 and a first terminal of resistor R2. A second terminal of resistor R2 is connected to ground. A base of transistor Q1 is connected between the switch SW1 and the second terminal of resistor R1. A first terminal of resistor R3 is connected to a collector of transistor Q1 and a second terminal of resistor R3 is connected to ground. An output of the collector of transistor Q1 is supplied to a first monostable integrated circuit (IC) U1. Capacitor C8 and a first pulse width control resistor R4 create a resistor-capacitor (RC) time constant for outputting a fixed length pulse from the first monostable U1. Capacitor C8 is connected between two particular terminal leads of the first monostable U1 and a first terminal of the first pulse width control resistor R4 is connected to one of the two particular terminal leads of the first monostable U1. A second terminal of the first pulse width control resistor R4 is connected to ground. A combination of transistor Q1 and the first monostable U1 form a de-bouncing circuit such that the transient component trigger 17 generates an output comprising a single clean trigger pulse when the switch SW1 is activated. The duration of the fixed length pulse supplied by the transient component trigger 17 is not dependent on a duration of a pulse generated by the switch SW1 being opened and closed. A leading or trailing edge of the pulse from the switch SW1 is used to initiate the generation of the fixed length pulse supplied by the transient component trigger 17 to activate the transient component generator 16.

The transient component duration adjuster 18 is a variable resistance comprising fixed resistor R5 and variable resistor POT in series. The variable resistance is connected to the transient component generator 16. The variable resistance in combination with a capacitance within the transient component generator 16 form a RC circuit having a RC time constant. A first terminal of variable resistor POT is supplied to the transient component generator 16. A second terminal of variable resistor POT is connected to a first terminal of fixed resistor R5. A second terminal of fixed resistor R5 is connected to ground. Adjusting variable resistor POT changes the RC constant of the RC circuit formed by the combination of the transient component duration adjuster 18 and the transient component generator 16. The change in the RC constant controls a duration of a pulse emitted by the transient component generator 16.

A central element of the transient component generator 16 is a second monostable U2, which receives the output from the transient component trigger 17. The second monostable U2 outputs a variable duration pulse based on the RC time constant formed by the variable resistance of the transient component duration adjuster 18 and the capacitance within the transient component generator 16. The capacitance within the transient component generator 16 is capacitor C7. Capacitor C7 is connected between two particular terminal leads of the second monostable U2 and the first terminal of variable resistor POT is connected to one of the two particular terminal leads of the second monostable U2.

The output of the second monostable U2 is supplied to a base of transistor Q2 via resistor R6. An emitter of transistor Q2 is connected to ground. A collector of transistor Q2 is connected to a first terminal of resistor R7. A second terminal of resistor R7 is connected to the first node. An output of the collector of transistor Q2 is supplied to a gate of a Field Effect Transistor (FET) Q3. A source of the FET Q3 is connected to the first node. A drain of the FET Q3 is an output of the transient component generator 16. The output of the transient component generator 16 is the output 15 of the transient insertion device 10.

The transient detector 19 also receives the output of the transient component generator 16. The transient detector 19 acts to stretch an input transient signal component for notification of an output of a signal by the transient component generator 16 used for the end result of modifying the timing signal. The output of the transient component generator 16 is supplied to a first terminal of resistor R8 and an emitter of transistor Q4. A second terminal of resistor R8 is connected to a base of transistor Q4. The second terminal of resistor R8 is also connected to a first terminal of resistor R9. A second terminal of resistor R9 is connected to ground. A collector of transistor Q4 is connected to a first terminal of resistor R10. A second terminal of resistor R10 is connected to ground. An output of the collector of transistor Q4 is connected to an input of a third monostable U3. Capacitor C11 and a second pulse width control resistor R18 create a RC time constant for outputting a fixed length pulse from the third monostable U3. Capacitor C11 is connected between two particular terminal leads of the third monostable U3 and a first terminal of the second pulse width control resistor R18 is connected to one of the two particular terminal leads of the third monostable U3. A second terminal of the second pulse width control resistor R18 is connected to ground. An output of the third monostable U3 is connected to a cathode of a light-emitting diode LED. An anode of the LED is connected to a first terminal of resistor R16. A second terminal of resistor R16 is connected to ground. The LED provides notification that the output from the transient component generator 16, which is used in modifying the timing signal, has been detected.

Referring to FIG. 2, in a particular embodiment monostables U1, U2, and U3 are the same “off the shelf” 74121 integrated circuit (IC) element. In the particular embodiment the power supply signal connected to the first node within the transient insertion device is a negative 5 volt supply voltage. The 74121 IC has three trigger inputs connected to a logic circuit within the IC. The IC provides a stable output pulse when A1 OR A2 goes low AND B goes high.

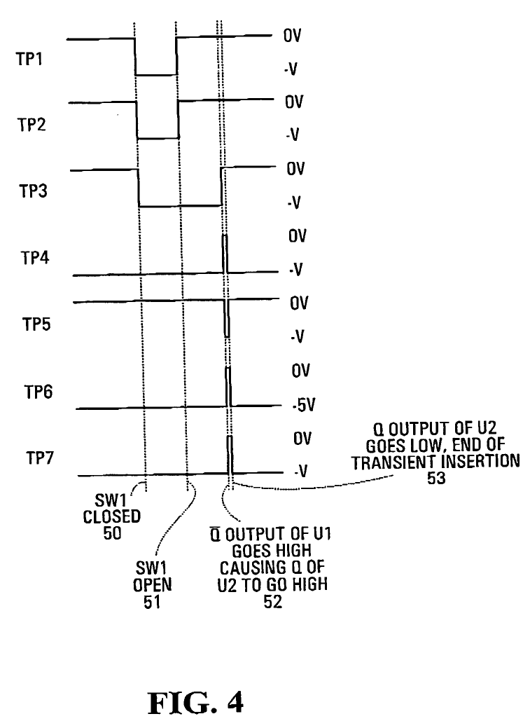

In the particular embodiment trigger inputs A1 and A2 of the first and second monostables U1, U2 are electrically connected to the first node providing for each monostable an active low on both trigger inputs A1 and A2. As shown in FIG. 2, the base of transistor Q1 is connected to the switch SW1. The collector of transistor Q1 is in turn connected to trigger input B of the first monostable U1. Referring to the timing diagram of FIG. 4, when the switch SW1 is “closed” 50 the base of transistor Q1 goes low as seen at Test Point 1 (TP1). This causes the trigger input B of the first monostable U1 to go low as well, seen at TP2. As a result, the trigger input B causes a complementary \overline{Q} output of the first monostable U1 to go low as seen at TP3. When the switch SW1 is “open” 51, the base of transistor Q1 goes high again, as seen at TP1. This causes the trigger input B of the first monostable U1 to go high again as well, as seen at TP2. A duration of the low at the complementary Q output of the monostable U1 is determined by the RC time constant of capacitor C8 and the first pulse width control resistor R4. The complementary \overline{Q} output of the first monostable U1 is a trigger input B to the second monostable U2. When the complementary \overline{Q} output of the first monostable U1 goes high 52 again, seen at TP3, the trigger input B to the second monostable U2 is high. This results in a positive pulse being triggered at a Q output of the second monostable U2, seen at TP4. The positive pulse output from the Q output of the second monostable U2 as seen at TP4, drives transistor Q2. Transistor Q2 in turn drives the FET Q3 with a pulse signal as seen at TP5. The FET Q3 creates a pulse, seen at TP6, which is the output of the transient insertion device 10. At the end of the duration of the positive pulse, the Q output of the second monostable U2 goes low 53 again, as seen at TP4, and the modification of the power supply signal supplied to the timing signal generator is completed.

The third monostable U3 is triggered by the active high from transistor Q4 seen at TP7, which causes the LED to turn on and provide visible notification that the transient signal component has been introduced within the power supply signal.

In other embodiments of the invention that are a functionally similar circuit implementation, the 74121 IC may be replaced by any IC element that can perform a functionally equivalent task when used appropriately. This may result in minor modification to the circuit, such as how pulse durations are varied and how resistors and capacitors are connected to an IC to create an appropriate RC constant.

In the particular embodiment, capacitor C8 and the first pulse width control resistor R4 nave values equal to 10 μf and 500 Ω, respectively. In the particular embodiment, capacitor C11 and the second pulse width control resistor R18 have values equal to 100 μf and 8.2 kΩ, respectively. In the particular embodiment, capacitor C7 has a value in the range of 1000 pf to 1000 μf and the variable resistance has a value for 15 the sum of fixed resistor R5 and variable resistor POT in the range of 1.4 kΩ to 30 kΩ. The range of the RC time constant generated by capacitor C7 and the sum of fixed resistor R5 and variable resistor POT result in a pulse duration in the range of 500 μs to 6.4 ms. More generally, the capacitance and resistance values used to create the RC time constant can be designed so that the pulse duration can be set anywhere in the range of nanoseconds to tens of seconds.

In other embodiments of the invention that are a functionally similar circuit implementation, the resistor and capacitor values which control the pulse widths of monostables U1, U2 and U3 are variable to the point that the transient insertion device 10 still provides at least a desired utility.

In the particular embodiment, monostables U1, U2 and U3 are each electrically powered by connecting a V_{cc} power terminal lead of the IC to ground and a ground terminal lead of the IC to the first node.

Resistors R1, R2, R3, R6, R7, R8, R9, R10, and R16 in the particular embodiment are 27 kΩ, 27 kΩ, 8.2 kΩ, 1.3 kΩ, 1.6 kΩ, 27 kΩ, 27 kΩ, 8.2 kΩ and 1.3 kΩ respectively. More generally, the resistors are variable in value so that the transient insertion device 10 still provides at least a desired utility. Capacitors C1, C2 and C3 provide noise suppression between ground and the power supply and are equal to 12 nf in the particular embodiment. More generally, capacitors C1, C2 and C3 each can be any value of capacitance that provides noise suppression but does not adversely affect the utility of the circuit.

In the particular embodiment, the switch SW1 is a push button switch which is “closed” when pressed and “open” when released. More generally, the switch SW1 can be any type of actuator that provides an opportunity to initiate modifying the power supply signal by supplying a trigger input to the transient component generator 16.

In the particular embodiment, the LED in the transient detector 19 is a light emitting diode (LED) which is activated when the transient component generator 16 is determined to have generated an output to modify the power supply signal. More generally, the LED can be replaced with any mechanism that can visibly relate when the transient component generator 16 is determined to have generated an output to modify the power supply signal, for example a LED display configured to display an alpha-numeric word or message or an LCD display configured to display an alphanumeric word or message.

In the particular embodiment, transistor Q1 is a 2N2222 transistor, transistor Q2 is a 2N2907A transistor, transistor Q3 is an N channel MOSFET transistor and transistor Q4 is a 2N2369 transistor. More generally, these elements can be substituted with electronic components of similar functionality, which provide at least the desired utility.

In a situation where a positive voltage power supply is used to power a timing signal generator instead of a negative voltage power supply, as described above with regard to FIG. 3, changes to the transient insertion device 10 are necessary. For example in the transient component generator 16, transistor Q3 would be a P channel MOSFET transistor, instead of an N channel transistor and transistor Q2 would be replaced with an appropriate npn transistor instead of a pnp transistor.

Referring to FIG. 2, in the particular embodiment where the second monostable U2 is a 74121 integrated circuit (IC) the duration of the variable duration pulse is governed by the variable resistance of the transient component duration adjuster 18 and capacitor C7 according to well known equations provided in application notes by the IC manufacturer.

FIG. 2 is a particular embodiment of the invention;

however those skilled in the art of electronics will realize that there are numerous implementations possible for the transient component generator 16, the transient component trigger 17, the transient component duration adjuster 18 and the transient detector 19.

In an effort to simulate a controlled fault, the invention acts to disrupt a power supply coupled to the timing signal generator one or more times, each time for a specific duration of time. One example of such a timing signal generator is a voltage-controlled oscillator (VCO); in particular a voltage controlled crystal oscillator (VCXO). Disrupting the power supply in a manner that denies power to the VCO causes the VCO to have zero output for the specific duration of time instead of a normal timing signal having a constant frequency. The zero output of the VCO has an effect of appearing as the transient signal component within the timing signal.

In some embodiments the power supply is modified by the transient insertion device 10 so that the power supplied to the timing signal generator is not reduced to a magnitude equal to zero, but is reduced to be less than a power level that is required to properly drive the timing signal generator.

FIG. 3 is an example of functional elements involved with modifying a timing signal by inserting at least one transient signal component within the timing signal, where one of the functional elements is the transient insertion device 10 of FIG. 1. The timing signal to be modified is generated using a conventional phase lock loop (PLL) as a timing signal generator in this example. A PPL 110 used in generating a timing signal has first and second inputs 111, 112 and first and second outputs 113, 114. The first input 111 is connected to a phase comparator 115. An output of the phase comparator 115 is supplied to a loop filter 116. An output of the loop filter 116 is supplied to a first input of a voltage controlled crystal oscillator VCXO 117. The VCXO 117 has first and second differential outputs which correspond to the first and second outputs 113, 114 of the PLL 110 respectively. The VCXO 117 has a third output that is supplied to a divider 118. An output of the divider 118 is supplied to the phase comparator 115. A −5 volt DC power supply 119 has an output that is supplied to the transient insertion device 10. An output of the transient insertion device 10 is supplied to the second input 112 of the PLL 110. The second input 112 of the PLL 110 is supplied to a second input of the VCXO 117.

In operation, a reference clock timing signal having a frequency f_{c} is supplied to the PLL 110 at the first input 111. The phase comparator 115 compares an instantaneous phase of the first input 111 with an instantaneous phase of the output of the divider 118. The output of the divider 118 has a frequency f_{d} that is equal to the free running frequency of the VCXO 117 fᵥ divided by the value of the divider 118. The phase comparator 115 outputs a voltage signal which is filtered by the loop filter 116 and used to drive the VCXO 117. The VCXO generates two differental output signals which form the timing signal at the first and second 113, 114 PLL outputs.

The power supply 119 is responsible for powering the VCXO 117. The transient insertion device 10 is located between the power supply 119 and the second input 112 to the PLL 110. The transient insertion device 10 acts as described above to alter the power supply signal from the power supply 119 before reaching the VCXO 117 within the PLL 110. By initiating a transient signal component at the power supply rail of the VCXO 117 using the transient insertion device 10, output buffers of the VCXO 117 are functionless, which results in a balanced output clock interruption as both differential outputs 113, 114 are interrupted simultaneously.

In the example described above pertaining to FIG. 3, the PLL described as the timing signal generator uses a VCXO. More generally, a non-crystal VCO could take the place of the VCXO.

In addition, it is noted that not all VCXOs or VCOs have two differential outputs as described above. In situations where a VCO has only a single output the transient insertion device 10 works in a similar manner to disrupt power supplied to the VCO so that a transient signal component is added to the single VCO output.

The timing signal generator is not always a PLL implementation. The timing signal generator can be simply a VCO or VCXO. In these situations the VCO is acted upon directly as the timing signal generator. More generally, the timing signal generator can be any type of oscillator, for example a fixed frequency oscillator.

In addition to the application of using the transient insertion device 10 for performing testing on devices that have failed in the field, the transient insertion device 10 has numerous other applications. For example, the transient insertion device 10 can be used as a fault simulator for development and robustness testing of timing elements such as VCXOs. Another usage of the transient insertion device 10 is as an oscilloscope calibration mechanism for validating a test set-up for identifying transient signal components caused by faulty VCXOs.

The device as described herein is adaptable for testing different types of timing signal generators and oscillator circuitry. In some embodiments, the timing signal generated by a timing signal generator is modified by altering the power supply signal from a power supply to the timing signal generator with multiple transient signal components to simulate various fault modes of the timing signal generator. In this situation the transient component trigger 17 is adapted to supply at least one trigger signal at a trigger spacing defined by a user, the transient component duration adjuster 18 is adapted to adjust the duration of multiple transient signal components independently or in a synchronized fashion, and the transient detector 19 provides visible notification when the power supply signal is modified by multiple transient signal components in a similar way as described above with respect to providing visible notification of modification of the power supply signal with only a single transient signal component.

Numerous modifications and variations of the present invention are possible in light of the above teachings. It is therefore to be understood that within the scope of the appended claims, the invention may be practised otherwise than as specifically described herein.

1. An apparatus adapted for modifying a timing signal, the apparatus comprising;
a power supply for supplying a power supply signal;
a timing signal generator which is coupled to and dependent upon the power supply for generating a timing signal; and
a transient insertion device which is electrically connected between the power supply and the timing signal generator for modifying the power supply signal to the timing signal generator by introducing at least one transient signal component into the power supply signal.

2. An apparatus according to claim 1, wherein the transient insertion device comprises;
a transient component trigger adapted to initiate modifying the power supply signal;
a transient component duration adjuster adapted to vary duration of the at least one transient signal component; and
a transient component generator which uses inputs supplied by the transient component trigger and the transient component duration adjuster to generate a modified power supply signal comprising at least one variable duration transient signal component, the timing signal being modified as a function of the modified power supply signal.

3. An apparatus according to claim 2, wherein the transient insertion device further comprises a transient detector adapted to provide notification of generation of the modified power supply signal.

4. An apparatus according to claim 2, wherein the transient insertion device is an electrical circuit comprised of discrete active and passive electrical components.

5. An apparatus according to claim 2, wherein the transient component trigger comprises an actuator for initiating the transient component generator to modify the power supply signal.

6. An apparatus according to claim 5, wherein the actuator is a manually activated switch.

7. An apparatus according to claim 4, wherein the transient component trigger further comprises a de-bouncing circuit adapted to provide a single trigger input to the transient component generator when the transient component trigger is activated.

8. An apparatus according to claim 4, wherein the transient component duration adjuster comprises a variable resistance.

9. An apparatus according to claim 8, wherein the variable resistance comprises a fixed resistor in series with a variable resistor.

10. An apparatus according to claim 4, wherein the transient component generator comprises at least one monostable integrated circuit (IC) which generates the at least one transient signal component, the duration of the at least one transient signal component is controlled by the transient component duration adjuster.

11. An apparatus according to claim 3, wherein the transient detector comprises means for determining if the modified power supply signal has been generated by the transient component generator.

12. An apparatus according to claim 11, wherein the transient detector further comprises means for notification of when the means for determining if the modified power supply signal has been generated by the transient component generator has determined the modified power supply signal has been generated.

13. An apparatus according to claim 12, wherein the means for notification comprises a mechanism for providing a visible notification when the means for determining if the modified power supply signal has been generated by the transient component generator has determined the modified power supply signal has been generated.

14. An apparatus according to claim 13, wherein the mechanism comprises a light emitting diode (LED) which is illuminated when the means for determining if the signal has been generated by the transient component generator to modify the timing signal has determined the signal has been generated.

15. An apparatus according to claim 1, wherein the at least one transient signal component is a single transient signal component.

16. An apparatus according to claim 1, wherein the timing signal generator is a phase locked loop circuit comprising;
a phase comparator for receiving a reference timing signal and comparing the reference signal to a signal output from a divider,
a filter for filtering an output of the phase comparator;
a voltage controlled oscillator (VCO) for generating the timing signal and for supplying an additional output signal to be acted upon by the divider, the VCO being electrically powered by a modified power supply signal output from the transient insertion device and the timing signal having a frequency that is a function of an output of the filter, and
the divider for dividing the frequency of the additional output signal from the VCO by an integer value.

17. An apparatus according to claim 16 where the VCO is voltage controlled crystal oscillator (VCXO).

18. An apparatus according to claim 1, wherein the timing signal generator is an oscillator.

19. An apparatus according to claim 18, wherein the oscillator is selected from a group consisting of a VCO, a VCXO and a fixed frequency oscillator.

20. A device adapted for modifying a power supply signal, the device comprising;
a transient component trigger adapted to initiate modifying the power supply signal;
a transient component duration adjuster adapted to vary duration of at least one transient signal component; and
a transient component generator which uses inputs supplied by the transient component trigger and the transient component duration adjuster to generate a modified power supply signal comprising at least one variable duration transient signal component.

21. A method of modifying a timing signal produced by a timing signal generator powered by a power supply signal, the method comprising introducing at least one transient signal component into the power supply signal.
